(19) United States
(12) Patent Application Publication
(10) Pub. No.: US 2024/0317153 A1
(43) Pub. Date: Sep. 26, 2024

(54) WIRE HARNESS

(71) Applicants: AUTONETWORKS TECHNOLOGIES, LTD., Yokkaichi-shi, Mie (JP); SUMITOMO WIRING SYSTEMS, LTD., Yokkaichi-shi, Mie (JP); SUMITOMO ELECTRIC INDUSTRIES, LTD., Osaka-shi, Osaka (JP)

(72) Inventors: Hiroki TAMARU, Yokkaichi-shi (JP); Yuichi KIMOTO, Yokkaichi-shi (JP)

(73) Assignees: AUTONETWORKS TECHNOLOGIES, LTD., Yokkaichi-shi, Mie (JP); SUMITOMO WIRING SYSTEMS, LTD., Yokkaichi-shi, Mie (JP); SUMITOMO ELECTRIC INDUSTRIES, LTD., Osaka-shi, Osaka (JP)

(21) Appl. No.: 18/270,099

(22) PCT Filed: Dec. 24, 2021
(86) PCT No.: PCT/JP2021/048425

§ 371 Date: Jun. 28, 2023

(30) Foreign Application Priority Data
Jan. 13, 2021 (JP) 2021-003654

(51) Int. Cl. B60R 16/02

(52) U.S. Cl. CPC B60R 16/0215

(57) ABSTRACT

A wire harness including: a wire; a metal tube in which the wire is housed; and an electromagnetic shield that surrounds an outer circumference of the wire that is drawn from the metal tube, wherein: the electromagnetic shield includes a sheet-shaped metal layer configured to be electrically connected to the metal tube, and the metal layer is made of a same type of metal as the metal tube.

### BACKGROUND

The present disclosure relates to a wire harness.

Conventionally, wire harnesses for use in vehicles such as a hybrid vehicle and an electric automobile include an electromagnetic shielding member that electromagnetically shields a plurality of wires collectively. As such an electromagnetic shielding member, an electromagnetic shielding member obtained by wrapping a metal foil so as to surround a plurality of wires collectively is known (see e.g., JP 2015-076899A). In a wire harness of this type, an end portion of the electromagnetic shielding member in the length direction is fixed to a metal shield shell using a crimping ring. Thus, the electromagnetic shielding member is grounded via the shield shell

### SUMMARY

Meanwhile, in conventional wire harnesses, electrolytic corrosion (electrochemical corrosion) occurs as a result of water adhering to a connection portion between the electromagnetic shielding member and the shield shell in the case where the electromagnetic shielding member and the shield shell are made of different types of metal.

An exemplary aspect of the disclosure provides a wire harness that can suppress the occurrence of electrolytic corrosion in an electromagnetic shielding member.

A wire harness according to the present disclosure includes: a wire; a metal tube in which the wire is housed; and an electromagnetic shield that surrounds an outer circumference of the wire that is drawn from the metal tube, wherein: the electromagnetic shield includes a sheet-shaped metal layer configured to be electrically connected to the metal tube, and the metal layer is made of a same type of metal as the metal tube.

The wire harness according to the present disclosure provides the effect of suppressing the occurrence of electrolytic corrosion in an electromagnetic shielding member.

### BRIEF DESCRIPTION OF THE DRAWINGS

FIG. 1 is a schematic configuration diagram showing a wire harness according to an embodiment.

FIG. 2 is a schematic cross-sectional view showing the wire harness according to an embodiment.

FIG. 3 is a schematic transverse sectional view showing the wire harness according to an embodiment.

FIG. 4 is a schematic perspective view showing the wire harness according to an embodiment.

FIG. 5 is a schematic cross-sectional view showing a wire harness according to a modification.

### DETAILED DESCRIPTION OF EMBODIMENTS

### Description of Embodiments of the Present Disclosure

First, embodiments of the present disclosure will be listed and described.
[1] A wire harness according to the present disclosure includes: a wire; a metal tubular member in which the wire is housed; and an electromagnetic shielding member that surrounds an outer circumference of the wire that is drawn from the tubular member, wherein the electromagnetic shielding member includes a sheet-shaped metal layer configured to be electrically connected to the tubular member, and the metal layer is made of the same type of metal as the tubular member.

With this configuration, the metal layer included in the sheet-shaped electromagnetic shielding member is made of the same type of metal as the tubular member. Accordingly, even if water adheres to a connection portion between the metal layer and the tubular member, it is possible to suppress the occurrence of electrolytic corrosion in the electromagnetic shielding member and the tubular member. This makes it possible to suppress a reduction in the electric connection reliability between the electromagnetic shielding member and the tubular member. Here, in the present specification, the same type of metals refer to metals having substantially the same ionization tendency. The expression “having substantially the same ionization tendency”, of course, includes a case where ionization tendencies are identical, and also includes a case where, even if ionization tendencies are different, the ionizations can be regarded as being substantially the same because they are similar.
[2] It is preferable that the metal layer has an inner circumferential surface facing the wire, and an outer circumferential surface on a side opposite to the inner circumferential surface, the electromagnetic shielding member includes a first resin layer formed on the outer circumferential surface of the metal layer, and the first resin layer has a higher emissivity than the metal layer. With this configuration, even when the metal layer has low emissivity, the outer circumferential surface of the metal layer is covered by the first resin layer having high emissivity. Accordingly, it is possible to increase heat radiation through emission as compared with a case where the first resin layer is not provided. This can improve the beat dissipation in the electromagnetic shielding member. Hence, it is possible to improve the heat dissipation of the wire harness.
[3] It is preferable that the electromagnetic shielding member includes a second resin layer formed on the inner circumferential surface of the metal layer, and the second resin layer has a higher emissivity than the metal layer. With this configuration, even when the metal layer has low emissivity, the inner circumferential surface of the metal layer is covered by the second resin layer having high emissivity. Accordingly, it is possible to increase heat radiation through emission as compared with a case where no second resin layer is provided. This can improve the heat dissipation in the electromagnetic shielding member, thus improving the heat dissipation of the wire harness.
[4] It is preferable that the first resin layer has a lower Young's modulus than the metal layer, and the second resin layer has a lower Young's modulus than the metal layer. With this configuration, the first resin layer and the second resin layer each having a lower Young's modulus than the metal layer are formed on the outer circumferential surface and the inner circumferential surface, respectively, of the metal layer. This makes it possible to increase the flexibility and extensibility of the electromagnetic shielding member as compared with a monolayer structure composed of only the metal layer. Accordingly, for example, at a bent portion of the wire, the electromagnetic shielding member can easily be made to conform to the shape of the bent portion, thus making it possible to suppress a breakage of the metal layer.
[5] It is preferable that the electromagnetic shielding member has a connection portion that is connected to an outer circumferential surface of the tubular member, and the inner circumferential surface of the metal layer at the connection portion is exposed from the second resin layer, and is in direct contact with the outer circumferential surface of the tubular member. With this configuration, at the connection portion, which is connected to the outer circumferential surface of the tubular member, of the electromagnetic shielding member, the inner circumferential surface of the metal layer that is exposed from the second resin layer is in direct contact with the outer circumferential surface of the tubular member. Accordingly, even when the second resin layer is formed on the inner circumferential surface of the metal layer, it is possible to electrically connect the metal layer and the tubular member to each other in a suitable manner.
[6] It is preferable that the wire harness further includes a fixing member configured to fix the electromagnetic shielding member to the tubular member while the metal layer is in contact with the tubular member. With this configuration, the electromagnetic shielding member is fixed to the tubular member using the fixing member while the metal layer is in contact with the tubular member. This makes it possible to stably maintain electrical conduction between the electromagnetic shielding member and the tubular member.
[7] It is preferable that the electromagnetic shielding member is formed in a tubular shape that surrounds an outer circumference of the tubular member, and the fixing member is a crimping ring configured to fasten the electromagnetic shielding member from outside toward the tubular member With this configuration, as a result of the electromagnetic shielding member being fastened by the crimping ring from outside toward the tubular member, the electromagnetic shielding member is fixed to the tubular member. This makes it possible to stably maintain electrical conduction between the electromagnetic shielding member and the tubular member.
[8] It is preferable that the fixing member is made of the same type of metal as the metal layer and the tubular member. With this configuration, the metal layer, the tubular member, and the fixing member of the electromagnetic shielding member are all made of the same type of metal. Accordingly, even if water adheres to the connection portion between the metal layer and the tubular member, and the connection portion between the electromagnetic shielding member and the crimping ring, it is possible to suppress the occurrence of electrolytic corrosion between the members. Accordingly, the connection portion between the metal layer and the tubular member can have a non-waterproof structure that is not provided with a rubber waterproofing cover or the like for covering the connection portion.
[9] It is preferable that the electromagnetic shielding member is formed in a sheet shape having an end face extending in a length direction of the wire, the electromagnetic shielding member has a first end portion in a first direction intersecting the length direction of the wire, and a second end portion provided on a side opposite to the first end portion in the first direction, and, as a result of the second end portion being overlapped with the first end portion, the electromagnetic shielding member is formed in a tubular shape that surrounds an outer circumference of the wire throughout a circumferential direction thereof. With this configuration, as a result of the second end of the sheet-shaped electromagnetic shielding member being overlapped with the first end thereof, the electromagnetic shielding member is formed so as to have a tubular shape that surrounds the outer circumference of the wire throughout the circumferential direction thereof. Accordingly, the electromagnetic shielding member can easily be attached to the wire at a later time. This can make it easier to assemble the wire harness.

### DETAILS OF EMBODIMENTS OF THE PRESENT DISCLOSURE

Specific examples of the wire harness according to the present disclosure will be described below with reference to the drawings. In the drawings, portions of configurations may be exaggerated or simplified for convenience of description. Also, dimensional proportions of the portions may differ between drawings. It should be noted that the present disclosure is not limited to these examples, and is intended to include all modifications which fall within the scope of the claims and the meaning and scope of equivalents thereof.

### Overall Configuration of Wire Harness 10

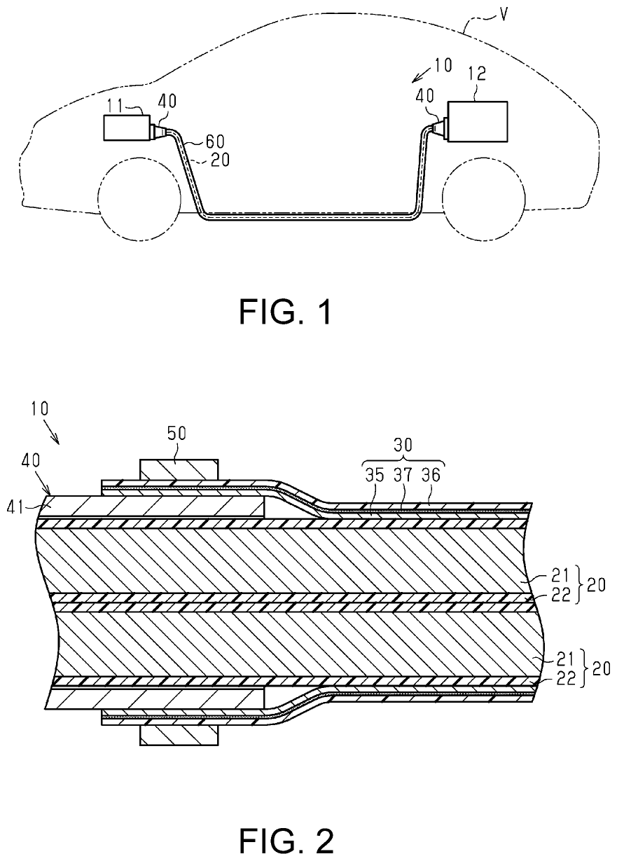

A wire harness 10 shown in FIG. 1 electrically connects two, or three or more electric devices 11 and 12. The electric devices 11 and 12 are installed in a vehicle V such as a hybrid vehicle or an electric automobile. Examples of the electric devices 11 and 12 include a battery, an inverter, a motor, an air conditioner device, a direction indicator device, and an air bag device.

As shown in FIGS. 1 and 2, the wire harness 10 includes one or more (two in the present embodiment) wires 20, an electromagnetic shielding member 30 (electromagnetic shield) that electromagnetically shields the plurality of wires 20, and a pair of connectors 40 attached to two end portions of the wires 20. As shown in FIG. 2, each connector 40 includes a metal tubular member 41 (metal tube).

As shown in FIG. 1, an end portion of each wire 20 is connected to the electric device 11 via one of the connectors 40, and the other end portion of the wire 20 is connected to the electric device 12 via the other connector 40. The wires 20 are two-dimensionally or three-dimensionally bent, for example.

### Configuration of Wire 20

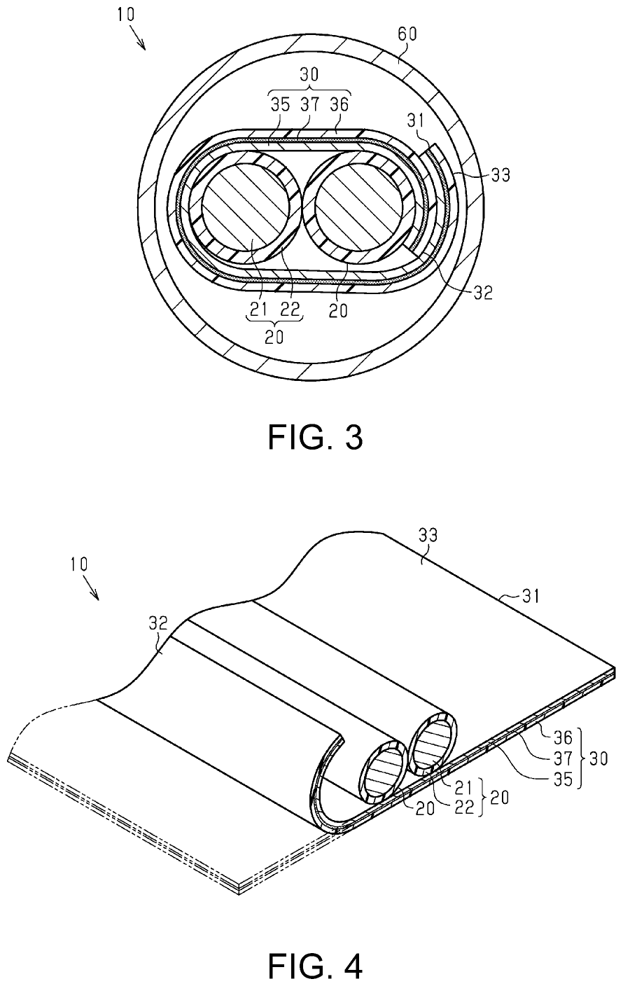

As shown in FIGS. 2 and 3, each wire 20 includes a conductive core wire 21, and an insulating coating 22 that covers the outer circumference of the core wire 21. The wire 20 is a non-shielded wire that does not have a shield structure of its own. The wire 20 is a high-voltage wire capable of handling a high voltage and a large current, for example.

The core wire 21 has an elongated shape. As the core wire 21, it is possible to use, for example, a stranded wire formed by twisting a plurality of metal strands together, a columnar conductor formed by a single columnar metal rod having a solid internal structure, a tubular conductor having a hollow structure, or the like. As the core wire 21, it is also possible to use, for example, a combination of a stranded wire, a columnar conductor, and a tubular conductor. As the material of the core wire 21, it is possible to use, for example, a metal material such as pure copper, a copper alloy, pure aluminum, and an aluminum alloy.

The transverse cross-sectional shape, or in other words, a cross-sectional shape of the core wire 21 taken along a plane orthogonal to the length direction of the core wire 21 can have any shape. The transverse cross-sectional shape of the core wire 21 has a circular shape, for example.

The insulating covering 22 surrounds the outer circumferential surface of the corresponding core wire 21 throughout the circumferential direction thereof, for example. The outer circumferential surface of the insulating coating 22 is has a shape corresponding to the outer circumferential surface of the core wire 21, for example. The insulating coating 22 according to the present embodiment has a cylindrical shape in which the inner and outer circumferences have a circular cross-sectional shape. For example, the insulating covering 22 is made of an insulating material such as a synthetic resin. The insulating covering 22 can be formed by performing extrusion molding (extrusion coating) on the core wire 21, for example.

As shown in FIG. 2, an end portion of each wire 20 in the length direction is inserted in the tubular member 41 of a connector 40. That is, an end portion of the wire 20 in the length direction is housed inside the tubular member 41. Of the wires 20 and the electromagnetic shielding member 30, only the wires 20 are inserted into the tubular member 41. Also, the wires 20 are drawn from the tubular member 41.

### Configuration of Electromagnetic Shielding Member 30

The electromagnetic shielding member 30 has an overall elongated tubular shape. The electromagnetic shielding member 30 is formed so as to surround the outer circumferences of the wires 20 that are drawn from the tubular member 41. For example, the electromagnetic shielding member 30 is formed so as to surround the outer circumferences of the plurality of wires 20 throughout the circumferential direction.

As shown in FIG. 4, the electromagnetic shielding member 30 is formed as a flexible sheet. For example, the electromagnetic shielding member 30 has an elongated sheet shape that extends in the length direction of the wires 20. For example, the electromagnetic shielding member 30 has an end face 31 extending in the length direction of the wires 20. The electromagnetic shielding member 30 has a width extending in a first direction intersecting the length direction of the wires 20. The electromagnetic shielding member 30 is formed so as to have a tubular shape by rolling up a flexible sheet material in the circumferential direction of the wires 20. For example, the electromagnetic shielding member 30 has an end portion 32 in the first direction intersecting the length direction of the wires 20, or in other words, the width direction of the electromagnetic shielding member 30, and an end portion 33 on the side opposite to the end portion 32 in the first direction. As shown in FIG. 3, the electromagnetic shielding member 30 is shaped into a tubular shape, for example, by overlapping the end portion 32 and the end portion 33 with each other in the radial direction of the wires 20. The electromagnetic shielding member 30 is formed so as to have a tubular shape, for example, by overlapping the end portion 33 with the outer circumferential surface of the end portion 32. For example, the inner circumferential dimension of the electromagnetic shielding member 30 can be adjusted to a dimension suited to the outer circumferential dimensions of the plurality of wires 20 by adjusting the overlap width between the end portion 32 and the end portion 33. For example, the electromagnetic shielding member 30 is elastically able to return from a tubular state in which the electromagnetic shielding member 30 is capable of surrounding the outer circumferences of the plurality of wires 20 to a sheet state in which the electromagnetic shielding member 30 does not surround the outer circumferences of the plurality of wires 20.

The electromagnetic shielding member 30 includes, for example, a metal layer 35, a resin layer 36, and a bonding layer 37 that bonds the metal layer 35 and the resin layer 36 to each other. That is, the electromagnetic shielding member 30 has a stacked structure in which the metal layer 35, the bonding layer 37, and the resin layer 36 are stacked in this order. For example, the electromagnetic shielding member 30 is disposed such that the metal layer 35 faces the wires 20. That is, the electromagnetic shielding member 30 is formed such that the metal layer 35 is disposed radially inward of the tubular-shaped electromagnetic shielding member 30. In other words, the electromagnetic shielding member 30 is formed such that the resin layer 36 is disposed radially outward of the tubular-shaped electromagnetic shielding member 30. For the sake of convenience, in the following description, among end faces of each of the members constituting the electromagnetic shielding member 30, an end face facing the wires 20 is referred to as an “inner circumferential surface”, and an end face on the side opposite to the inner circumferential surface is referred to as an “outer circumferential surface”.

The metal layer 35 has a sheet shape. The metal layer 35 has an electromagnetic shielding function. As the metal layer 35, it is possible to use a sheet material made of a metal foil or a metal material, for example. As the material of the metal layer 35, it is possible to use a metal material such as pure copper, a copper alloy, pure aluminum, and an aluminum alloy, for example. The metal layer 35 according to the present embodiment is a metal foil made of pure aluminum.

The bonding layer 37 is bonded to the metal layer 35, and is also bonded to the resin layer 36. The bonding layer 37 is bonded to the outer circumferential surface of the metal layer 35, and is also bonded to the inner circumferential surface of the resin layer 36. The bonding layer 37 is formed so as to cover the outer circumferential surface of the metal layer 35. For example, the bonding layer 37 is formed so as to cover the entire outer circumferential surface of the metal layer 35. As the bonding layer 37, it is possible to use, for example, an epoxy resin-based, polyurethane-based, or acrylic resin-based adhesive. As the bonding layer 37, it is also possible to use a conductive adhesive, for example.

The resin layer 36 has a sheet shape. The resin layer 36 is formed so as to cover the outer circumferential surface of the bonding layer 37. For example, the resin layer 36 is formed so as to cover the entire outer circumferential surface of the bonding layer 37. For example, the size of the resin layer 36 is formed according to the size of the metal layer 35. As the material of the resin layer 36, it is possible to use, for example, a resin material having higher emissivity than the metal layer 35. The emissivity of the resin layer 36 can be set to 0.7 or more, for example. As the material of the resin layer 36, it is possible to use, for example, a resin material having a lower Young's modulus than the metal layer 35. As the material of the resin layer 36, it is possible to use, for example, a conductive resin material or a non-conductive resin material. As the material of the resin layer 36, it is possible to use, for example, a synthetic resin such as polypropylene (PP), polyethylene terephthalate (PET), and polyethylene (PE).

Here, in general, the metal (e.g., aluminum) that forms the metal layer 35 has good thermal conductivity, but in many cases has poor emissivity. For example, the emissivity of aluminum is 0.1 or less. Therefore, the resin layer 36 having higher emissivity than the outer circumferential surface of the metal layer 35 is bonded to that outer circumferential surface. This can increase heat radiation through emission as compared with a case where no resin layer 36 is formed.

In this case, according to Wien's displacement law, the peak of the wavelength of light emitted from an object through heat radiation is inversely proportional to the temperature of the object. Also, it is known that the value of emissivity of an object formed by the same material varies depending on the temperature (wavelength of light) of the object. Since the wire harness 10 is mounted in the vehicle V (see FIG. 1) in the present embodiment, it is preferable that the resin layer 36 has a high emissivity for a peak wavelength in a high temperature range that may occur in a usage environment of the vehicle.

At the overlapping portion between the end portions 32 and 33 of the electromagnetic shielding member 30, the inner circumferential surface of the metal layer 35 at the end portion 33 is in contact with the outer circumferential surface of the resin layer 36 at the end portion 32. At the overlapping portion between the end portions 32 and 33, the metal layer 35 at the end portion 32 and the metal layer 35 at the end portion 33 are disposed overlapping each other in the radial direction of the wires 20. Accordingly, the metal layer 35 is wrapped in two layers.

The electromagnetic shielding member 30 according to the present embodiment does not include a bonding surface or adhesive surface. Specifically, in the electromagnetic shielding member 30 of the present embodiment, no bonding surface or adhesive surface is formed on the inner circumferential surface of the metal layer 35 and the outer circumferential surface of the resin layer 36. The electromagnetic shielding member 30 is kept in a tubular state, for example, by wrapping a binding member (not shown) therearound. As the binding member, it is possible to use, for example, a tape member or a cable tie. For example, binding members are provided at predetermined intervals in the length direction of the electromagnetic shielding member 30.

### End Portion Structure of Wire Harness 10

As shown in FIG. 2, an end portion of the electromagnetic shielding member 30 in the length direction is connected to the outer circumferential surface of the tubular member 41. That is, an end portion of the electromagnetic shielding member 30 in the length direction constitutes a connection portion (connection) that is connected to the tubular member 41. At the end portion of the electromagnetic shielding member 30 in the length direction, the inner circumferential surface of the metal layer 35 is in contact with the outer circumferential surface of the tubular member 41. Thus, the electromagnetic shielding member 30 is electrically connected to the tubular member 41. Although not shown, the electromagnetic shielding member 30 is grounded to a vehicle body panel or the like via the tubular member 41.

For example, the wire harness 10 includes a crimping ring 50 that fixes the electromagnetic shielding member 30 to the tubular member 41 while the metal layer 35 is in contact with the tubular member 41. The crimping ring 50 is attached to the outer circumferential surface of the tubular member 41. The crimping ring 50 has a tubular shape along the outer circumferential surface of the tubular member 41. For example, the tubular member 41 has a cylindrical shape, and the crimping ring 50 is formed in a cylindrical shape along the outer circumferential surface of the tubular member 41. The crimping ring 50 is fitted to the outside of the tubular member 41 in a manner in which the end portion of the electromagnetic shielding member 30 in the length direction is sandwiched between the crimping ring 50 and the outer circumferential surface of the tubular member 41, for example. Also, as a result of the crimping ring 50 being fastened radially inward of the tubular member 41, the end portion of the electromagnetic shielding member 30 in the length direction is fixed to the outer circumferential surface of the tubular member 41 in direct contact therewith. That is, the end portion of the electromagnetic shielding member 30 in the length direction is fastened by the crimping ring 50 from outside toward the tubular member 41 so as to be fixed to the outer circumferential surface of the tubular member 41 while the inner circumferential surface of the metal layer 35 is in direct contact with the outer circumferential surface of the tubular member 41. Thus, electrical conduction between the electromagnetic shielding member 30 and the tubular member 41 can be stably maintained. In addition, the electromagnetic shielding member 30 can be kept in a tubular state by the crimping ring 50. Note that the inner circumferential surface of the crimping ring 50 is in contact with the outer circumferential surface of the resin layer 36.

As the material of the tubular member 41, it is possible to use, for example, an iron-based, aluminum-based, or copper-based metal material. The tubular member 41 may be subjected to surface treatment such as tin plating and aluminum plating according to the type and usage environment of its constituent metal. That is, the tubular member 41 may have a structure obtained by forming a plating film on the surface of a base material.

As the material of the crimping ring 50, it is possible to use, for example, an iron-based, aluminum-based, or copper-based metal material. The crimping ring 50 may be subjected to surface treatment such as tin plating and aluminum plating according to the type and usage environment of its constituent metal. That is, the crimping ring 50 may have a structure obtained by forming a plating film on the surface of a base material

### Combination of Materials of Metal Layer 35, Tubular Member 41, and Crimping Ring 50

Here, the metal layer 35 of the electromagnetic shielding member 30 is made of the same type of metal as the tubular member 41. In the present specification, the same type of metals refer to metals having substantially the same ionization tendency. The expression “having substantially the same ionization tendency”, of course, includes a case where ionization tendencies are identical, and also includes a case where, even if ionization tendencies are different, the ionizations can be regarded as being substantially the same because they are similar. The range where the ionization tendencies of a first metal and a second metal can be regarded as being substantially the same includes a combination of metals that does not cause electrolytic corrosion when the first metal and the second metal are electrically connected to each other via an aqueous solution containing an electrolyte, and also includes a combination of metals that may cause electrolytic corrosion, but does not impose a practical problem for use in a vehicle or the like. The metal layer 35 is made of the same type of metal as the outermost surface of the tubular member 41. For example, when the tubular member 41 has a structure obtained by forming a plating film on the surface of a base material, the plating film and the metal layer 35 are made of the same type of metal.

The crimping ring 50 of the present embodiment is made of the same type of metal as the metal layer 35 and the tubular member 41. For example, when the crimping ring 50 has a structure obtained by forming a plating film on the surface of a base material, the plating film is made of the same type of metal as the metal layer 35.

In the present embodiment, the metal layer 35 is composed of pure aluminum or an aluminum alloy, the tubular member 41 is composed of an aluminum alloy, and the crimping ring 50 is composed of an aluminum alloy. Specifically, as the material of the metal layer 35, it is possible to use a 1000-series aluminum alloy including pure aluminum, or an 8000-series aluminum alloy. As the material of the tubular member 41, it is possible to use a 3000-series aluminum alloy, or a die-casting aluminum alloy (ADC material). Examples of the ADC material include an aluminum alloy ADC3 and an aluminum alloy ADC12. When the metal layer 35 is made of pure aluminum or an aluminum alloy, it is preferable that a 3000-series aluminum alloy, which contains a small amount of copper, is used as the material of the tubular member 41, from the viewpoint of preventing electrolytic corrosion. As the tubular member 41, it is also possible to use a structure obtained by plating a base material made of an iron alloy with molten aluminum, thereby forming an aluminum plating film on the surface of the base material. Note that, as the iron alloy, it is possible to use, for example, carbon steel, special steel, or stainless steel. The crimping ring 50 of the present embodiment has a structure obtained by plating a base material made of an iron alloy with molten aluminum, thereby forming an aluminum plating film on the surface of the base material.

### Configuration of Exterior Member 60

As shown in FIG. 3, the wire harness 10 includes an exterior member 60 that surrounds the outer circumference of the electromagnetic shielding member 30, for example. The exterior member 60 has an overall elongated tubular shape. For example, the exterior member 60 is formed so as to surround the outer circumference of the electromagnetic shielding member 30 throughout the circumferential direction. The electromagnetic shielding member 30 and the plurality of wires 20 covered by the electromagnetic shielding member 30 are housed inside the exterior member 60. The exterior member 60 protects the wires 20 and the electromagnetic shielding member 30 housed thereinside from flying objects and water droplets Note that the illustration of the exterior member 60 has been omitted in FIG. 2.

As the exterior member 60, it is possible to use, for example, a pipe or a corrugated tube made of metal or resin, a resin waterproofing cover made of rubber, or a combination thereof. As the material of the pipe or corrugated tube made of metal, it is possible to use, for example, an aluminum-based or copper-based metal material. As the material of the pipe or corrugated tube made of resin, it is possible to use, for example, a conductive resin material or a non-conductive resin material. As the resin material, it is possible to use, for example, a synthetic resin such as polyolefin, polyamide, polyester, and an ABS resin.

Next, operations and effects of the present embodiment will be described.
(1) The metal layer 35 of the electromagnetic shielding member 30 is made of the same type of metal as the tubular member 41. In the present embodiment, the metal layer 35 and the tubular member 41 are all made of an aluminum-based metal material. Accordingly, even if water adheres to the connection portion between the metal layer 35 and the tubular member 41, it is possible to suitably suppress the occurrence of electrolytic corrosion. Thus, it is possible to suppress a reduction in the electromagnetic shielding performance of the electromagnetic shielding member 30 due to electrolytic corrosion. Also, the connection portion between the metal layer 35 and the tubular member 41 may have a non-waterproof structure that is not provided with a rubber waterproofing cover or the like for covering the connection portion. In other words, even with a non-waterproof structure, it is possible to suppress the occurrence of electrolytic corrosion in the metal layer 35 and the tubular member 41. As a result, it is possible to suppress an increase in the size of the wire harness 10, and an increase in the number of components.
(2) The resin layer 36 having higher emissivity than the metal layer 35 is formed on the outer circumferential surface of the metal layer 35. With this configuration, even when the metal layer 35 has low emissivity, the outer circumferential surface of the metal layer 35 is covered by the resin layer 36 having high emissivity. Accordingly, it is possible to increase heat radiation through emission as compared with a case where no resin layer 36 is provided. Therefore, for example, even when the outer circumferential surface of the electromagnetic shielding member 30 and the inner circumferential surface of the exterior member 60 are physically separated from each other, heat can be efficiently conducted from the outer circumferential surface of the electromagnetic shielding member 30 to the exterior member 60 through emission. This can improve the heat dissipation in the electromagnetic shielding member 30, thus improving the heat dissipation of the wire harness 10.
(3) The resin layer 36 having a lower Young's modulus than the metal layer 35 is formed on the outer circumferential surface of the metal layer 35. With this configuration, it is possible to increase the flexibility and extensibility of the electromagnetic shielding member as compared with a monolayer structure composed only of the metal layer 35. Accordingly, for example, at a bent portion of the wires 20, the electromagnetic shielding member 30 can easily be made to conform to the shape of the bent portion, thus making it possible to suppress breakage of the metal layer 35.
(4) Of the inner circumferential surface and the outer circumferential surface of the metal layer 35, the resin layer 36 is formed only on the outer circumferential surface. That is, the resin layer is not formed on the inner circumferential surface of the metal layer 35. Accordingly, when fixing the end portion of the electromagnetic shielding member 30 in the length direction to the tubular member 41, the inner circumferential surface of the metal layer can be brought into direct contact with the outer circumferential surface of the tubular member 41. Thus, the electromagnetic shielding member 30 and the tubular member 41 can be electrically connected to each other at the end portion of the electromagnetic shielding member 30 in the length direction, or in other words, the connection portion thereof with the tubular member 41 in a suitable manner, without performing a step of stripping off the resin layer, for example.
(5) When a conductive resin material is used as the material of the resin layer 36, the electromagnetic shielding function can be maintained using the resin layer 36 even if the metal layer 35 breaks at a bent portion of the wires 20.
(6) Provided is the crimping ring 50 that fixes the electromagnetic shielding member to the tubular member 41 while the metal layer 35 is in contact with the tubular member 41. With this configuration, as a result of the electromagnetic shielding member 30 being fastened by the crimping ring 50 from outside toward the tubular member 41, the electromagnetic shielding member 30 is fixed to the tubular member 41 while the inner circumferential surface of the metal layer 35 is in contact with the outer circumferential surface of the tubular member 41. Thus, electrical conduction between the electromagnetic shielding member 30 and the tubular member 41 can be stably maintained.
(7) The crimping ring 50 is made of the same type of metal as the metal layer 35 of the electromagnetic shielding member 30 and the tubular member 41. With this configuration, the metal layer 35, the tubular member 41, and the crimping ring 50 are all made of the same type of metal. Accordingly, even if water adheres to the connection portion between the metal layer 35 and the tubular member 41, and the connection portion between the electromagnetic shielding member 30 and the crimping ring 50, it is possible to suppress the occurrence of electrolytic corrosion between the members. For example, even when the metal layer 35 and the crimping ring 50 are electrically connected to each other via water, it is possible to suppress the occurrence of electrolytic corrosion between the metal layer 35 and the crimping ring 50. Accordingly, the connection portion between the metal layer 35 and the tubular member 41 can have a non-waterproof structure that is not provided with a rubber waterproofing cover or the like for covering the connection portion.
(8) As a result of the end portion 33 of the sheet-shaped electromagnetic shielding member 30 being overlapped with the end portion 32 thereof, the electromagnetic shielding member 30 has a tubular shape that surrounds the outer circumferences of the wires 20 throughout the circumferential direction. Accordingly, the electromagnetic shielding member can be easily attached to the wires 20 at a later time. This can make it easier to assemble the wire harness 10.
(9) Furthermore, by adjusting the overlap width between the end portion 32 and the end portion 33, it is possible to easily adjust the inner circumferential dimension and the outer circumferential dimension of the electromagnetic shielding member 30 according to the outer circumferential dimension of the wires 20. This can suitably suppress an increase in the outer circumferential dimension of the electromagnetic shielding member 30.

### OTHER EMBODIMENTS

The above embodiment can be implemented with the following modifications. The above embodiment and the following modifications can be implemented in combination with each other as long as there are no technical discrepancies.

In the electromagnetic shielding member 30 of the above embodiment, of the inner circumferential surface and the outer circumferential surface of the metal layer 35, the resin layer 36 is formed only on the outer circumferential surface. However, the present disclosure is not limited thereto.

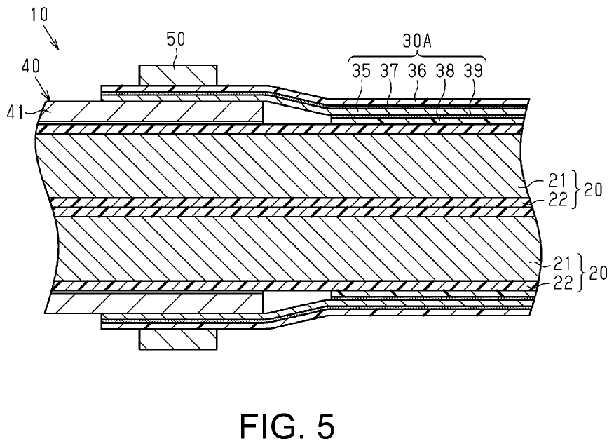

For example, as shown in FIG. 5, the resin layer 36 may be formed on the outer circumferential surface of the metal layer 35, and a resin layer 38 may be formed on the inner circumferential surface of the metal layer 35. In an electromagnetic shielding member 30A of this modification, the resin layer 38 is bonded to the inner circumferential surface of the metal layer 35 via a bonding layer 39. That is, the electromagnetic shielding member 30A has a stacked structure in which the resin layer 38, the bonding layer 39, the metal layer 35, the bonding layer 37, and the resin layer 36 are stacked in this order from the inner circumferential surface side of the electromagnetic shielding member 30. For example, the electromagnetic shielding member 30A is disposed such that the resin layer 38 faces the wires 20.

The bonding layer 39 is bonded to the inner circumferential surface of the metal layer 35, and is bonded to the outer circumferential surface of the resin layer 38. The bonding layer 39 is formed so as to cover the inner circumferential surface of the metal layer 35. As the bonding layer 39, it is possible to use, for example, an epoxy resin-based, polyurethane-based, or acrylic resin-based adhesive.

The resin layer 38 has a sheet shape. The resin layer 38 is formed so as to cover the outer circumferential surface of the bonding layer 39. For example, the resin layer 38 is formed so as to cover the entire outer circumferential surface of the bonding layer 39. As the material of the resin layer 38, it is possible to use, for example, a resin material having higher emissivity than the metal layer 35. The emissivity of the resin layer 38 can be set to 0.7 or more, for example. As the material of the resin layer 38, it is possible to use, for example, a resin material having a lower Young's modulus than the metal layer 35. As the material of the resin layer 38, it is possible to use, for example, a conductive resin material or a non-conductive resin material. As the material of the resin layer 38, it is possible to use, for example, a synthetic resin such as polypropylene, polyethylene terephthalate, and polyethylene.

An end portion of the electromagnetic shielding member 30A in the length direction is connected to the outer circumferential surface of the tubular member 41. That is, an end portion of the electromagnetic shielding member 30A in the length direction constitutes a connection portion that is connected to the tubular member 41. At the connection portion of the electromagnetic shielding member 30A, the inner circumferential surface of the metal layer is exposed from the resin layer 38, and the inner circumferential surface of the metal layer is in direct contact with the outer circumferential surface of the tubular member 41. In other words, at the connection portion of the electromagnetic shielding member 30A, the bonding layer 39 and the resin layer 38 are not formed on the inner circumferential surface of the metal layer 35. Accordingly, at the connection portion of the electromagnetic shielding member 30A, the inner circumferential surface of the metal layer 35 can be brought into direct contact with the outer circumferential surface of the tubular member 41. Thus, even when the resin layer 38 is formed on the inner circumferential surface of the metal layer 35, the metal layer 35 and the tubular member 41 can be electrically connected to each other in a suitable manner.

With the above-described configuration, even when the metal layer 35 has low emissivity, the inner circumferential surface of the metal layer 35 is covered by the resin layer 38 having high emissivity. This makes it possible to increase heat radiation through emission as compared with a case where no resin layer 38 is provided. Therefore, for example, even when the inner circumferential surface of the electromagnetic shielding member 30, here, the inner circumferential surface of the resin layer 38, and the outer circumferential surfaces of the wires 20 are physically separated from each other, heat can be efficiently conducted from the outer circumferential surfaces of the wires 20 to the electromagnetic shielding member 30 through emission. Furthermore, since the outer circumferential surface of the metal layer 35 is covered by the resin layer 36 having high emissivity, heat can be efficiently conducted from the outer circumferential surface of the electromagnetic shielding member 30 to the exterior member 60 (see FIG. 3) through emission. This makes it possible to increase heat dissipation in the wire harness 10. As a result, an increase in the temperature of the wires 20 can be kept low, and it is therefore possible to reduce the size of the core wires 21 of the wires 20, or reduce the thickness of the insulating coatings 22.

Since the resin layer 38 having a lower Young's modulus than the metal layer 35 is formed on the inner circumferential surface of the metal layer 35, it is possible to increase the flexibility and extensibility of the electromagnetic shielding member 30A as compared with a case where no resin layer 38 is provided. Accordingly, for example, at a bent portion of the wires 20, the electromagnetic shielding member 30A can be easily made to conform to the shape of the bent portion, thus making it possible to further suppress breakage of the metal layer 35.
The bonding layer 37 and the resin layer 36 may be omitted from the electromagnetic shielding member 30A shown in FIG. 5. The electromagnetic shielding member 30A in this case is composed of the metal layer 35, and the resin layer 38 bonded to the inner circumferential surface of the metal layer 35 using the bonding layer 39.

The bonding layer 37 and the resin layer 36 may be omitted from the electromagnetic shielding member 30 described above. The electromagnetic shielding member 30 in this case is composed only of the metal layer 35

In the above embodiment, the resin layer 36 is bonded to the outer circumferential surface of the metal layer 35 using the bonding layer 37. However, the present disclosure is not limited thereto. For example, the resin layer 36 may be formed by performing a coating treatment in which a coating material having a higher emissivity than the metal layer 35 is coated onto the outer circumferential surface of the metal layer 35. In this case, the bonding layer 37 is omitted.

In the electromagnetic shielding member 30A shown in FIG. 5, the resin layer 38 is bonded to the inner circumferential surface of the metal layer 35 using the bonding layer 39. However, the present disclosure is not limited thereto. For example, the resin layer 38 may be formed by performing a coating treatment in which a coating material having a higher emissivity than the metal layer 35 is coated onto the inner circumferential surface of the metal layer 35. In this case, the bonding layer 39 is omitted.

A bonding layer or an adhesive layer may be provided on one surface of the electromagnetic shielding member 30 of the above embodiment. For example, a bonding layer or an adhesive layer may be provided on the outer circumferential surface of the end portion 32 of the electromagnetic shielding member 30. With this configuration, when overlapping the end portion 33 of the electromagnetic shielding member 30 with the end portion 32 thereof, the end portion 33 can be bonded to the end portion 32. Accordingly, it is possible to suitably prevent the electromagnetic shielding member 30 from returning to the sheet state at a stage before the electromagnetic shielding member 30 is fixed using the crimping ring 50 or the like.

There is no particular limitation on the manner in which the electromagnetic shielding member 30 is wrapped in the above embodiment. In the above embodiment, the electromagnetic shielding member 30 is formed in a tubular shape by overlapping the end portions 32 and 33 of the electromagnetic shielding member 30 in the width direction with each other. The present disclosure is not limited thereto. For example, the electromagnetic shielding member 30 may be formed in a tubular shape by overlapping intermediate portions of the electromagnetic shielding member 30 in the width direction with each other. In this case, the end portions 32 and 33 of the electromagnetic shielding member 30 in the width direction need not be overlapped with each other That is, the inner circumferential surface of the end portion 33 need not be in contact with the outer circumferential surface of the end portion 32. Also, the electromagnetic shielding member 30 may be wrapped around the wires so as to form two overlapped layers throughout the circumferential direction of the electromagnetic shielding member 30.

In the above embodiment, the inner circumferential surface and the outer circumferential surface of the electromagnetic shielding member 30 in the sheet state before the electromagnetic shielding member 30 is wrapped are formed to be planar. However, the present disclosure is not limited thereto. For example, a plurality of slits may be formed in the inner circumferential surface and the outer circumferential surface of the electromagnetic shielding member 30. The plurality of slits may be formed so as to facilitate bending of the electromagnetic shielding member 30. For example, in the case where the plurality of slits formed in each of the inner circumferential surface and the outer circumferential surface of the electromagnetic shielding member 30 extend in the length direction of the wires 20, the electromagnetic shielding member 30 can easily undergo bending deformation so as to conform to the outer circumferential surfaces of the wires 20 when wrapping the electromagnetic shielding member 30 around the outer circumferential surfaces of the wires 20. In the case where the plurality of slits formed in each of the inner circumferential surface and the outer circumferential surface of the electromagnetic shielding member 30 extend in a direction intersecting or orthogonal to the length direction of the wires 20, the electromagnetic shielding member 30 wrapped around the outer circumferential surfaces of the wires 20 can easily undergo bending deformation so as to conform to a bent portion located on a routing path of the wires 20. The plurality of slits are useful, for example, in reducing bending creases in the metal layer 35 of the electromagnetic shielding member 30 that may form as a result of bending deformation of the electromagnetic shielding member 30.

In the above embodiment, the crimping ring 50 is embodied as a structure obtained by forming an aluminum plating film on a base material made of an iron alloy. However, the present disclosure is not limited thereto. For example, the base material of the crimping ring 50 may be composed of an aluminum alloy. For example, the crimping ring 50 in this case can be formed as follows. First, a cylindrical aluminum alloy pipe having an inner diameter larger than the outer diameter of the tubular member 41 is disposed outside of the electromagnetic shielding member 30 provided so as to surround the outer circumference of the tubular member 41. That is, the aluminum alloy pipe is disposed outside the electromagnetic shielding member 30 so as to overlap the tubular member 41 and the electromagnetic shielding member 30 in the radial direction. Subsequently, using a mold or the like, the aluminum alloy pipe is pressed radially inward, substantially throughout the circumferential direction. Thus, the aluminum alloy pipe is plastically deformed so as to have a reduced diameter, thus forming a crimping ring 50.

The metal layer 35, the tubular member 41, and the crimping ring 50 in the above embodiment may all be composed of a copper-based metal material. The metal layer 35, the tubular member 41, and the crimping ring 50 may all be composed of a tin-based metal material.

In the above embodiment, the crimping ring 50 is composed of the same type of metal as the metal layer 35 and the tubular member 41. The present disclose is not limited thereto. For example, the, crimping ring 50 may be composed of a different type of metal from the metal layer 35 and the tubular member 41.

In the above embodiment, the crimping ring 50 is used as the fixing member that fixes the end portion of the electromagnetic shielding member 30 to the outer circumferential surface of the tubular member 41 in an electrically connected state. However, the present disclosure is not limited thereto. For example, a metal band, a resin cable tie, adhesive tape, or the like may be used as a fixing member in place of the crimping ring 50.

In the above embodiment, the tubular member to which the electromagnetic shielding member 30 is connected is embodied as the tubular member 41 included in the connector 40. However, the present disclosure is not limited thereto. For example, the tubular member to which the electromagnetic shielding member 30 is connected may be embodied as a metal pipe constituting the exterior member 60. In this case, the connection portion between the electromagnetic shielding member 30 and the tubular member is located at an intermediation portion of the wire harness 10 in the length direction.

In the above embodiment, the electromagnetic shielding member 30 is provided inside the exterior member 60. However, the present disclosure is not limited thereto. For example, the electromagnetic shielding member 30 may be provided outside the exterior member 60. The electromagnetic shielding member 30 in this case is provided so as to surround the outer circumference of the exterior member 60.

The exterior member 60 may be omitted from the wire harness 10 in the above embodiment.

In the above embodiment, the number of wires 20 constituting the wire harness 10 is two. However, the present disclosure is not limited thereto. The number of wires 20 may be changed according to the specifications of the vehicle V. For example, the number of wires may be one, or three or more. For example, low-voltage wires that connect a low-voltage battery to various low-voltage devices (e.g., a lamp, a car audio system, etc.) may be additionally provided as the wires constituting the wire harness 10.

The positional relationship between the electric device 11 and the electric device 12 in the vehicle V is not limited to that of the above embodiment, and may be changed as appropriate according to the configuration of the vehicle.

As shown in FIGS. 2 to 4, the electromagnetic shielding member 30 is formed in an elongated tubular shape, and is provided such that the end portion of the electromagnetic shielding member 30 in the length direction covers the outer circumference of the tubular member 41. The metal layer 35 disposed radially inward of the electromagnetic shielding member 30 may be in direct contact with the tubular member 41 without any other member interposed therebetween, and a waterproofing member that seals the contact portion between the metal layer 35 and the tubular member 41 in a watertight state need not be provided.

The metal tubular member 41 of each connector 40 may be a grounded shield shell of the connector 40. The metal layer 35 of the electromagnetic shielding member 30 may continuously extend between two connectors 40 at two ends of the wires 20, and electrically connect the metal tubular members 41 of the two connectors 40 to each other. The metal layer 35 of the tubular electromagnetic shielding member 30 shown in FIGS. 3 and 4 may be referred to as a metal foil roll that extends over the entire length of the electromagnetic shielding member 30.

It should be appreciated that the embodiments disclosed herein are to be construed in all respects as illustrative and not limiting. The scope of the present disclosure is defined by the claims, rather than the description of the embodiment above, and is intended to include all modifications which fall within the scope of the claims and the meaning and scope of equivalents thereof.

1. A wire harness comprising:
a wire;
a metal tube in which the wire is housed; and
an electromagnetic shield that surrounds an outer circumference of the wire that is drawn from the metal tube, wherein:
the electromagnetic shield includes a sheet-shaped metal layer configured to be electrically connected to the metal tube, and
the metal layer is made of a same type of metal as the metal tube.

2. The wire harness according to claim 1, wherein:
the metal layer has an inner circumferential surface facing the wire, and an outer circumferential surface on a side opposite to the inner circumferential surface,
the electromagnetic shield includes a first resin layer formed on the outer circumferential surface of the metal layer, and
the first resin layer has higher emissivity than the metal layer.

3. The wire harness according to claim 2, wherein:
the electromagnetic shield includes a second resin layer formed on the inner circumferential surface of the metal layer, and
the second resin layer has higher emissivity than the metal layer.

4. The wire harness according to claim 3, wherein:
the first resin layer has a lower Young's modulus than the metal layer, and
the second resin layer has a lower Young's modulus than the metal layer.

5. The wire harness according to claim 3, wherein:
the electromagnetic shield has a connection that is connected to an outer circumferential surface of the metal tube, and
the inner circumferential surface of the metal layer at the connection is exposed from the second resin layer, and is in direct contact with the outer circumferential surface of the metal tube.

6. The wire harness according to claim 1, further comprising
a fixing member configured to fix the electromagnetic shield to the metal tube while the metal layer is in contact with the metal tube.

7. The wire harness according to claim 6, wherein:
the electromagnetic shield is formed in a tubular shape that surrounds an outer circumference of the metal tube, and
the fixing member is a crimping ring configured to fasten the electromagnetic shield from outside toward the metal tube.

8. The wire harness according to claim 6,
wherein the fixing member is made of a same type of metal as the metal layer and the metal tube.

9. The wire harness according to claim 1, wherein:
the electromagnetic shield is formed in a sheet shape having an end face extending in a length direction of the wire,
the electromagnetic shield has a first end in a first direction intersecting the length direction of the wire, and a second end provided on a side opposite to the first end in the first direction, and
as a result of the second end being overlapped with the first end, the electromagnetic shield is formed in a tubular shape that surrounds an outer circumference of the wire throughout a circumferential direction thereof.
